(19) United States
(12) Patent Application Publication
(10) Pub. No.: US 2010/0007409 A1
(43) Pub. Date: Jan. 14, 2010

(54) Method and Related Device for an Adjustable Leading Edge Blanking Device in a Power Supply Device

(76) Inventors: Yen-Hui Wang, Hsinchu City (TW); Chia-Chieh Hung, Taoyuan County (TW); Chin-Yen Lin, Hsinchu County (TW)

Correspondence Address: NORTH AMERICA INTELLECTUAL PROPERTY CORPORATION, P.O. BOX 506, MERRIFIELD, VA, 22116, US

(21) Appl. No.: 12/172,273

(22) Filed: Jul. 14, 2008

(51) Int. Cl. H03K 5/00

(52) U.S. Cl. 327/551

(57) ABSTRACT

A method for an adjustable leading edge blanking device in a power supply device includes generating a detection signal according to a leading edge and a trailing edge of a spike signal, generating a blanking signal according to the detection signal, for blanking the spike signal between the leading edge and the trailing edge, and controlling output states of the power supply device according to the blanking signal.

### BACKGROUND OF THE INVENTION

1. Field of the Invention

The present invention relates to a method and a related device for an adjustable leading edge blanking device in a power supply device, and more particularly, to a method and a related device for improving the adjustable leading edge blanking device according to a blanking signal.

2. Description of the Prior Art

A switching power supply can transform AC to DC and output a stable, appropriate voltage for kinds of electronic devices, such as computers, office automatic systems, industrial instruments, and communications equipments.

Please refer to FIG. 1, which is a schematic diagram of a switching power supply 10 according to the prior art. The switching power supply 10 shown in FIG. 1 simply comprises a driving unit 100, a switch transistor Q1, a current-sense resistor Rs and related components. The driving unit 100 is coupled to a gate and a drain of the switch transistor Q1 and is utilized for outputting a pulse signal to control output an on/off state of the switch transistor Q1, for transforming an input voltage VIN to an output voltage VOUT. The current-sense resistor Rs is coupled between the drain of the switch transistor Q1 and a ground terminal. The driving unit 100 senses a current Id (Vs=Rs×Id) according to a current-sense signal VSEN1. When the voltage level of the current-sense signal VSEN1 reaches a threshold, the driving unit 100 starts operations of an over-current protection device in the driving unit 100 according to an over-current detection signal OC1, and outputs the pulse signal to turn off the switch transistor Q1 for cutting off the current Id, for avoiding passing an over current to the load.

Usually, a spike signal appears during a turn-on transition of the switch transistor Q1, which results in an abnormal high voltage level of the current-sense signal VSEN1 and a feedback circuit of the switching power supply 10 making a wrong decision accordingly. Therefore, the driving unit 100 starts operations of the over-current protection device of the switching power supply 10 according to the detection of an over current that does not happen in fact. In the prior art, there is a leading edge blanking device in the driving unit 100, which operates in order to avoid abnormal start of the over-current protection device. The leading edge blanking device generates a blanking signal LEB1 for controlling output states of the over-current detection signal OC1. That is, the blanking signal LEB1 is used for ignoring the voltage level variance of the current-sense signal VSEN1 during a default time, for blanking the spike signal.

Please refer to FIG. 2 for a timing diagram of the current-sense signal VSEN1, the blanking signal LEB1 and the over-current detection signal OC1. In FIG. 2, waveforms of the blanking signal LEB1 and the over-current detection signal OC1 is simply presented by high/low voltage level; the threshold is 0.85V, for example. When a spike signal appears, the blanking signal LEB1 transforms from high to low during a leading edge of the spike signal and stays in low voltage level for a default time T1, such as 350 ns. During the default time T1, the driving unit 100 stops outputting the over-current detection signal OC1 according to the blanking signal LEB1, for stopping operations of the over-current protection device. After the default time T1, the blanking signal LEB1 transforms from low to high, and the driving unit 100 outputs the over-current detection signal OC1 according to the blanking signal LEB1, and thereby the over-current protection device resumes operating. Therefore, when the voltage level of the current-sense signal VSEN1 exceeds 0.85V at a time point A′, the over-current protection device will turn off the switch transistor Q1 to protect the load from being damaged by the over current.

At the same time, the voltage level of the current-sense signal VSEN1 rises quickly when the switching power supply 10 operates in a short-circuit mode. When the current-sense signal VSEN1 exceeds 0.85V at a time point A during the default time T1, as shown in FIG. 2, the switching power supply 10 still stops outputting the over-current detection signal OC1 according to the blanking signal LEB1. In this situation, the over-current protection device fails to operate and the driving unit 100 cannot detect the over current happening at the time point A. Therefore, the load may be damaged by the over current.

### SUMMARY OF THE INVENTION

It is therefore a primary objective of the claimed invention to provide a method and a related device for an adjustable leading edge blanking device in a power supply device.

The present invention discloses a method for an adjustable leading edge blanking device in a power supply device. The method comprises generating a detection signal according to a leading edge and a trailing edge of a spike signal, generating a blanking signal according to the detection signal, for blanking the spike signal between the leading edge and the trailing edge, and controlling output states of the power supply device according to the blanking signal.

The present invention further discloses an adjustable leading edge blanking device for a power supply device, which comprises a spike detection unit, a logic unit and a control unit. The spike detection unit is utilized for generating a detection signal according to a leading edge and a trailing edge of a spike signal. The logic unit is coupled to the spike detection unit and is utilized for generating a blanking signal according to the detection signal, for blanking the spike signal between the leading edge and the trailing edge. The control unit is coupled to the logic unit and is utilized for controlling output states of the power supply device according to the blanking signal.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram of a switching power supply according to the prior art.

FIG. 2 is a timing diagram of a current-sense signal, a blanking signal and an over-current detection signal of the switching power supply shown in FIG. 1.

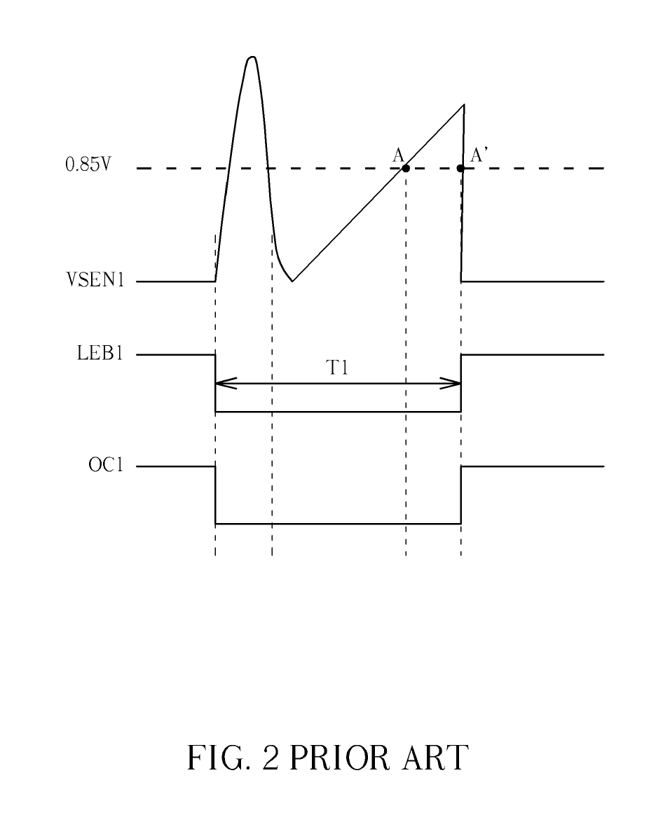

FIG. 3 is a flowchart of a process according to an embodiment of the present invention.

FIG. 4 is a timing diagram of related signals in the process shown in FIG. 3 according to an embodiment of the present invention.

FIG. 5 is a schematic diagram of an adjustable leading edge blanking device according to an embodiment of the present invention.

### DETAILED DESCRIPTION

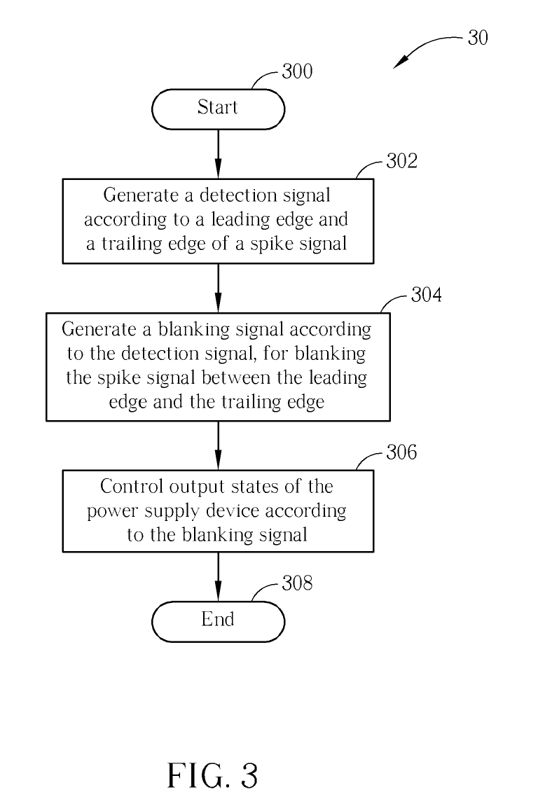

Please refer to FIG. 3, which is a flowchart of a process 30 according to an embodiment of the present invention. The process 30 is utilized for an adjustable leading edge blanking device in a power supply device and comprises the following steps:

Step 300: Start.

Step 302: Generate a detection signal according to a leading edge and a trailing edge of a spike signal.

Step 304: Generate a blanking signal according to the detection signal, for blanking the spike signal between the leading edge and the trailing edge.

Step 306: Control output states of the power supply device according to the blanking signal.

Step 308: End.

In the process 30, the power supply device is a switching power supply device. The spike signal appears during a turn-on transition of a switch transistor in the primary side of the power supply device. According to the process 30, the power supply device detects the leading edge and the trailing edge of the spike signal and generates the blanking signal accordingly. The power supply device then controls an on/off state of the over-current protection device according to the blanking signal, and further controls output states of the power supply device. In detail, during the leading edge of the spike signal, the power supply device stops outputting an over-current detection signal according to the blanking signal in order to stop operations of the over-current protection device, for ignoring the spike signal and continuing outputting power source. On the other hand, during the trailing edge of the spike signal, the power supply device starts to output the over-current detection signal according to the blanking signal, for starting operations of the over-current protection device. Therefore, when the voltage level of a current-sense signal sensed by a drain of the switch transistor exceeds a threshold, the power supply device stops outputting power source for preventing the load from being damaged by the over current.

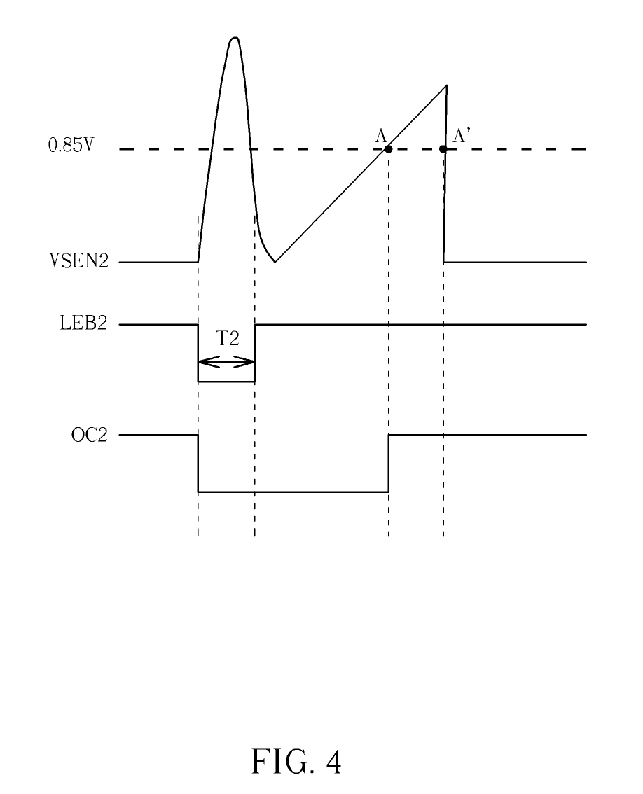

Please refer to FIG. 4, which is a timing diagram of related signals in the process 30. The current-sense signal VSEN2 is in an abnormal high voltage level during the turn-on transition of the switch transistor. During the time T2 between the leading edge and the trailing edge of the spike signal, the power supply device stops outputting the over-current detection signal OC2 according to the blanking signal LEB2. After the time T2, the power supply device returns to output the over-current detection signal OC2. Note that, the length of the time T2 depends on different requirements in the implementation. In the prior art switching power supply 10, the default time T1 is 350 ns. Compared with the prior art, the embodiment of the present invention reduces the time T2 to be 50% of the default time T1, and even 25% of the default time T1, which is approximately 85 ns. Note that, the power supply device returns to output the over-current detection signal OC2 during the trailing edge of the spike signal. That is, the over-current protection device resumes operating during the trailing edge of the spike signal. As a result, when the current-sense signal VSEN2 exceeds the threshold, 0.85V, the power supply device starts the over-current protection device for stopping outputting power source, for preventing the load from being damaged by the over current.

In the prior art, the power supply device returns to output the over-current detection signal OC1 after the default time T1. When the voltage level of the current-sense signal VSEN1 exceeds the threshold during the default time T1, the power supply device fails to start the over-current protection device, which results in possible damage on the load. In comparison, the embodiment of the present invention controls the power supply device to return to output the over-current detection signal OC2 during the trailing edge of the spike signal. Therefore, the abnormal operation of the power supply device caused by the spike signal is avoided, and the power supply device can detect the over current happening after the spike signal.

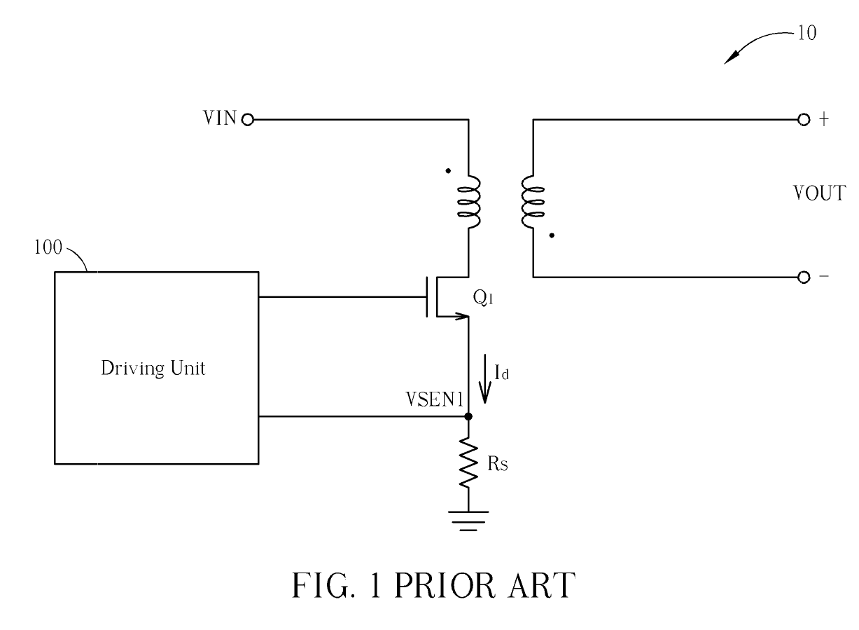

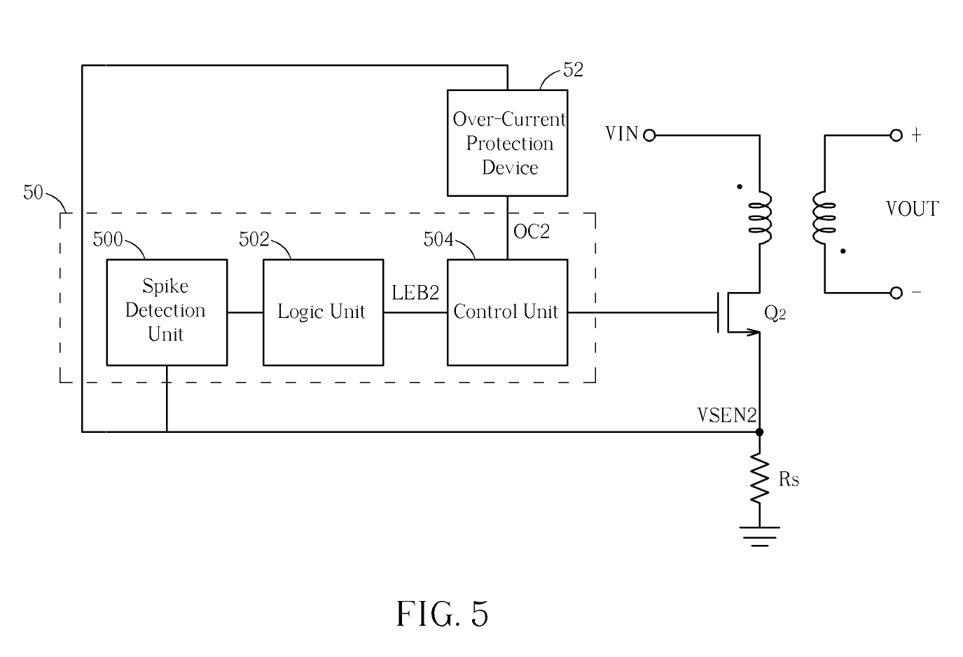

Please refer to FIG. 5 for the implementation of the process 30. FIG. 5 is a schematic diagram of an adjustable leading edge blanking device 50 in a power supply device according to an embodiment of the present invention. The power supply device is a switching power supply, such as the prior art switching power supply 10 shown in the FIG. 1. The adjustable leading edge blanking device 50 is utilized for controlling an over-current protection device 52 of the power supply device and comprises a spike detection unit 500, a logic unit 502 and a control unit 504. The spike detection unit 500 is coupled to a drain of a switch transistor Q2 in the primary side of the power supply device and is utilized for generating a detection signal according to a leading edge and a trailing edge of a spike signal. The logic unit 502 is coupled to the spike detection unit 500 and the control unit 504, and is utilized for generating a blanking signal according to the detection signal, for blanking the spike signal between the leading edge and the trailing edge. The control unit 504 is coupled to the logic unit 502, a gate of the switch transistor Q2 and the over-current protection device 52, and is utilized for controlling an on/off state of the over-current protection device 52 according to the blanking signal, and thereby controlling output states of the power supply device. The detailed operations of the adjustable leading edge blanking device 50 is described in the process 30 and are not given here.

In conclusion, the embodiment of the present invention blanks the spike signal between the leading edge and the trailing edge according to the blanking signal, and controls the over-current protection device to resume operating during the trailing edge of the spike signal. The power supply device can stop outputting power source when detecting the over current, and therefore prevents the load from being damaged.

Those skilled in the art will readily observe that numerous modifications and alterations of the device and method may be made while retaining the teachings of the invention.

What is claimed is:

1. A method for an adjustable leading edge blanking device in a power supply device comprising:
generating a detection signal according to a leading edge and a trailing edge of a spike signal;
generating a blanking signal according to the detection signal, for blanking the spike signal between the leading edge and the trailing edge; and
controlling output states of the power supply device according to the blanking signal.

2. The method of claim 1, wherein the spike signal appears during a turn-on transition of a switch transistor in the primary side of the power supply device.

3. The method of claim 1, wherein the step of controlling output states of the power supply device according to the blanking signal comprises stopping operations of an over-current protection device of the power supply device during the leading edge of the spike signal, for continuing outputting power source.

4. The method of claim 3, wherein the step of controlling output states of the power supply device according to the blanking signal further comprises starting operations of the over-current protection device during the trailing edge of the spike signal, for stopping outputting power source while the voltage level of a current-sense signal exceeds a threshold.

5. The method of claim 1, wherein the power supply device is a switching power supply.

6. The method of claim 1, wherein the time between the leading edge and the trailing edge of the spike signal is less than 30% of a default time.

7. The method of claim 1, wherein the time between the leading edge and the trailing edge of the spike signal is less than 50% of a default time.

8. An adjustable leading edge blanking device for a power supply device comprising:
a spike detection unit, for generating a detection signal according to a leading edge and a trailing edge of a spike signal;
a logic unit coupled to the spike detection unit, for generating a blanking signal according to the detection signal, for blanking the spike signal between the leading edge and the trailing edge; and
a control unit coupled to the logic unit, for controlling output states of the power supply device according to the blanking signal.

9. The adjustable leading edge blanking device of claim 8, wherein the spike detection unit is coupled to a drain of a switch transistor in the primary side of the power supply device.

10. The adjustable leading edge blanking device of claim 9, wherein the spike signal appears during a turn-on transition of a switch transistor in the primary side of the power supply device.

11. The adjustable leading edge blanking device of claim 8, wherein the control unit is further coupled to a gate of a switch transistor and an over-current protection device in the primary side of the power supply device.

12. The adjustable leading edge blanking device of claim 8, wherein the control unit is further utilized for stopping operations of an over-current protection device of the power supply device during the leading edge of the spike signal, for continuing outputting power source.

13. The adjustable leading edge blanking device of claim 12, wherein the control unit is further utilized for starting operations of the over-current protection device during the trailing edge of the spike signal, for stopping outputting power source while the voltage level of a current-sense signal exceeds a threshold.

14. The adjustable leading edge blanking device of claim 8, wherein the power supply device is a switching power supply.

15. The adjustable leading edge blanking device of claim 8, wherein the time between the leading edge and the trailing edge of the spike signal is less than 30% of a default time.

16. The adjustable leading edge blanking device of claim 8, wherein the time between the leading edge and the trailing edge of the spike signal is less than 50% of a default time.
